(19) United States
(12) Patent Application Publication
(10) Pub. No.: US 2010/0012999 A1
(43) Pub. Date: Jan. 21, 2010

(54) SEMICONDUCTOR MEMORY DEVICE AND METHOD OF MANUFACTURING THE SAME

(76) Inventor: Ji Hwan Park, Chungju-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/493,309

(22) Filed: Jun. 29, 2009

(30) Foreign Application Priority Data
Jul. 15, 2008 (KR) 10-2008-0068533

(51) Int. Cl. H01L 29/792; H01L 21/336

(52) U.S. Cl. 257/324; 438/287; 257/E29.309; 257/E21.423

(57) ABSTRACT

Provided are a semiconductor memory device and a method of manufacturing the same. The semiconductor memory device comprises two gate electrodes on a semiconductor substrate between device isolation regions, a common source region on the semiconductor substrate between the two gate electrodes, a drain region on the semiconductor substrate at outer sides of the two gate electrodes, a spacer on the drain region and on outer sidewalls of the two gate electrodes, a third oxide layer on inner sidewalls of the two gate electrodes, and a silicide layer on the common source region.

### CROSS-REFERENCE TO RELATED APPLICATION

The present application claims the benefit under 35 U.S.C. § 119 of Korean Patent Application No. 10-2008-0068533, filed Jul. 15, 2008, which is hereby incorporated by reference in its entirety.

### BACKGROUND

The present disclosure relates to a semiconductor memory device and a method of manufacturing the same.

In general, a semiconductor memory device is classified into a Random Access Memory (RAM) and a Read Only Memory (ROM). The RAM is volatile and thus loses its stored data as time elapses, but has fast input and output. The ROM retains its stored data and maintains its status, but has slow input and output.

Recently, a demand for Electrically Erasable Programmable ROM (EEPROM) and a flash memory, which can program or erase data, has increased drastically.

A flash memory cell having a collectively erasing function has a stack gate structure where a floating gate and a control gate are stacked. The flash memory is divided into a NAND type and a NOR type. In the NAND type, sixteen cells are typically connected in series to constitute a unit string, and this unit string is connected in parallel between a bit line and a ground line. In the NOR type, each cell is connected in parallel between a bit line and a ground line. The NAND flash memory is advantageous to the high degree of integration. The NOR flash memory is advantageous to the high speed operation. The NOR flash memory uses a common source method. That is, one contact is formed per, for example, sixteen cells, and a source line of the sixteen cells is typically connected to an n+ diffusion layer.

In order to improve the degree of integration in a flash memory device, an interval between memory cells becomes gradually decreased, and especially, when a Self Aligned Source (SAS) structure is used, a common source region is covered by a spacer.

Accordingly, when a silicide process is performed, the spacer prevents silicide from being formed in a common source region. Because the silicide is not formed, the resistance value of the common source region is drastically increased.

Especially, if Shallow Trench Isolation (STI) and SAS techniques are applied simultaneously during manufacturing of the flash memory, the source resistance at each cell is increased compared to when LOCal Oxidation of Silicon (LOCOS) process is applied. If the source resistance at each cell is increased, because one source contact is formed by each sixteen cells, a back bias may vary according to a voltage drop between the first cell and the eighth cell. Consequently, an error occurs during a read operation.

Moreover, since a peripheral region of the flash memory uses a high voltage of approximately 12 V and a cell region uses a low voltage of approximately 5 V to approximately 9V, as the flash memory becomes more micronized, the depth of a trench becomes deeper.

As the source resistance increases, there becomes a current flow difference between a cell adjacent to an electrode and a cell far from the electrode. Thus, an operational characteristic between the cells vary. That is, the operational reliability of a semiconductor device becomes deteriorated.

### BRIEF SUMMARY

Embodiments provide a semiconductor memory device and a method of manufacturing the same. The semiconductor memory device according to an embodiment removes a spacer influence and forms a silicide layer in a common source region even if an interval between devices becomes narrower as a memory device becomes more highly integrated and micronized. Accordingly, the semiconductor memory device can allow a current flow between a cell adjacent to an electrode and a cell far from the electrode to be uniform.

In one embodiment, a semiconductor memory device comprises: two gate electrodes on a semiconductor substrate between device isolation regions; a common source region on the semiconductor substrate between the two gate electrodes; a drain region on the semiconductor substrate at outer sides of the two gate electrodes; a spacer on the drain region and on the outer sidewalls of the two gate electrodes; a third oxide layer on inner sidewalls of the two gate electrodes, the inner sidewalls facing each other; and a silicide layer on the common source region.

In another embodiment, a method of manufacturing a semiconductor memory device comprises: forming two gate electrodes on a semiconductor substrate between device isolation regions; forming a common source region in the semiconductor substrate between the two gate electrodes and forming a drain region between each gate electrode and the device isolation region; forming a spacer on the drain region, the common source region, and sidewalls of each gate electrode, the spacer including a third oxide layer, a second nitride layer, and a fourth oxide layer; removing the fourth oxide layer and the second nitride layer disposed between the gate electrodes and removing the third oxide layer disposed on the common source region; and forming a silicide layer on the exposed common source region.

The details of one or more embodiments are set forth in the accompanying drawings and the description below. Other features will be apparent from the description and drawings, and from the claims.

### BRIEF DESCRIPTION OF THE DRAWINGS

FIG. 1 is a plan view illustrating a structure of a semiconductor memory device according to an embodiment.

FIG. 2 is a side-sectional view taken along the line A-A′ and illustrates a structure of a semiconductor memory device according to an embodiment.

FIGS. 3-6 show side-sectional views taken along line B-B′ for illustrating a method of fabricating a semiconductor memory device according to an embodiment.

FIG. 7 is a side-sectional view taken along the line C-C′ of FIG. 1 and illustrates a structure of a semiconductor memory device according to an embodiment.

### DETAILED DESCRIPTION

A semiconductor memory device and a method of manufacturing the same according to an embodiment will be described in detail with reference to the accompanying drawings.

Hereinafter, during description about an embodiment, detailed descriptions related to well-known functions or configurations will be left out in order not to obscure subject matters of the present invention. Thus, only core components, which are directly related to the novel features of the present invention, will be mentioned below.

In the description of embodiments, it will be understood that when a layer (or film), region, pattern or structure is referred to as being ‘on’ or ‘under’ another layer (or film), region, pad or pattern, the terminology of ‘on’ and ‘under’ includes both the meanings of ‘directly’ and ‘indirectly’. Further, the reference about ‘on’ and ‘under’ each layer will be made on the basis of drawings.

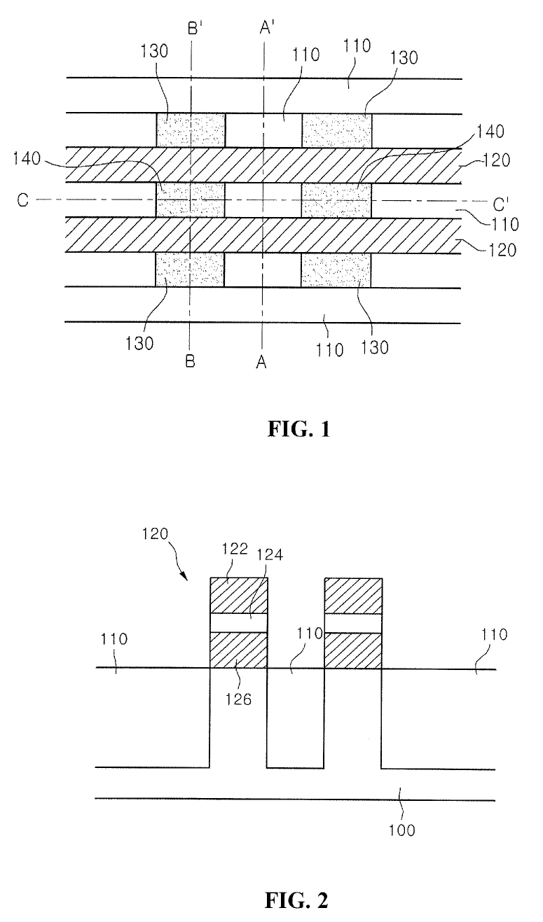

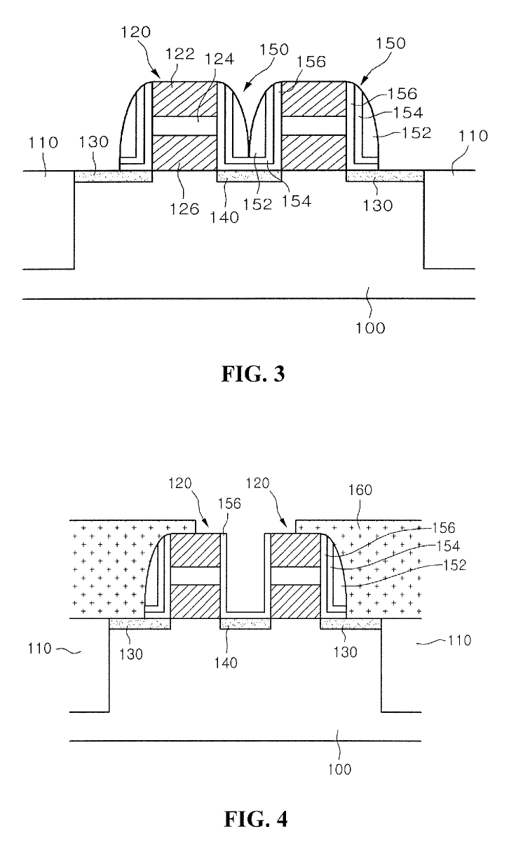

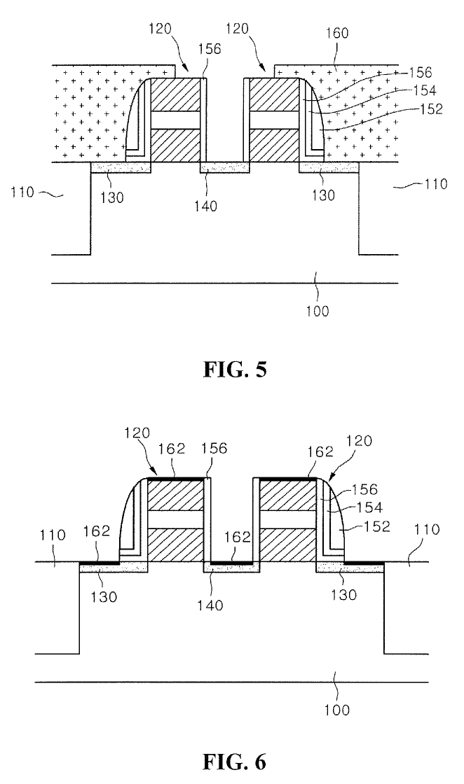

FIG. 1 is a plan view illustrating a structure of a semiconductor memory device according to an embodiment. FIG. 2 is a side-sectional view taken along the line A-A′ and illustrates a structure of a semiconductor memory device according to an embodiment. FIG. 3 is a side-sectional view taken along the line B-B′ and illustrates a structure after a spacer in a semiconductor memory device is formed according to an embodiment.

In order for the high degree of integration in a semiconductor device, a Shallow Trench Isolation (STI) technique and a Self Aligned Source (SAS) can be used.

In the description below, a semiconductor memory device according to an embodiment is directed to a flash memory device having a STI structure and a SAS structure. Cells of the flash memory device may be reduced in an x-axis and y-axis directions by the STI structure and the SAS structure.

Referring to FIGS. 1 to 3, two lines for gate electrodes 120 are formed laterally on the semiconductor substrate 100 in the x-axis direction and a common source region 140 is formed between the two lines for the gate electrodes 120.

Then, drain regions 130 are formed at outer sides of the two lines for the gate electrodes 120.

The common source region 140 and the drain region 130 are aligned to a region corresponding to the y-axis direction.

The two lines for the gate electrodes 120 are insulated in the y-axis direction by the device isolation region 110 disposed at intervals along the x-axis. The common source region 140 and the drain region 130 are insulated in the x-axis direction by the device isolation region 110 at the outer sides of the two gate electrode lines 120.

In an embodiment, a trench is formed in the semiconductor substrate 100 to define the device isolation region 110. An insulation layer is formed on the semiconductor substrate 100 by filling the trench. Next, the insulation layer is planarized to expose the surface of the semiconductor substrate 100 so that the device isolation region 110 is formed.

Once the device isolation region 110 is formed, the gate lines 120 can be formed. For example, as shown in FIGS. 2 and 3, the gate lines 120 can include a floating gate 126, an insulating layer 124, such as an Oxide-Nitride-Oxide (ONO) structure, and a control gate 122 can be formed on the semiconductor substrate 100. The ONO structure can be formed by sequentially stacking a first oxide layer, a first nitride layer and a second oxide layer on the floating gate layer, and etching the second oxide layer, the first nitride layer, and the first oxide layer using a photoresist pattern defining the gate electrode region. The control gate layer can be etched using the photoresist pattern before etching the second oxide layer of the ONO structure. The floating gate layer can also be etched using the photoresist pattern.

Next, an ion implantation process can be performed on an active region between the gate lines 120 and the device isolation region 110 to form the common source region 140 and the drain region 130.

Referring to FIG. 3, a spacer 150 can be formed on the common source region 140, a portion the drain region, and both sidewalls of each of the two gate lines 120.

It should be noted that FIG. 1 does not illustrate the spacer in order to show a structure of the common source region 140 and the drain region 130.

The spacer 150 has an ONO structure of a third oxide layer 156, a second nitride layer 154, and a fourth oxide layer 152, which can be similar to the insulating layer of the gate electrode 120.

FIG. 4 is a side-sectional view taken along the line B-B′ of FIG. 1 and illustrates a structure after the fourth oxide layer 152 and the second nitride layer 154 are partially removed according to an embodiment.

Referring to FIG. 4, a photoresist layer is applied to an entire surface of the semiconductor substrate 100, and reticle alignment, development, exposure, and cleaning processes are performed on a photoresist pattern 160.

The photoresist pattern 160 forms an open region to expose the spacer structure 150 on the common source region 140, and is formed to cover the spacer structure 150 on the drain region, the drain region 130, and the device isolation region 110.

Next, a first etching process is performed using the photoresist pattern 160 as an etching mask.

The fourth oxide layer 152 in the spacer structure 150 on the common source region 140 is removed through the first etching process.

Next, a second etching process is performed using the photoresist pattern 160 as an etching mask.

The second nitride layer 154 in the spacer structure 150 on the common source region 140 is removed through the second etching process.

The first etching process and the second etching process can be performed through a wet etching method having an isotropic etching characteristic.

FIG. 5 is a side-sectional view taken along the line B-B′ of FIG. 1 and illustrates a structure after the third oxide layer 156 is partially removed in a semiconductor memory device according to an embodiment.

For example, referring to FIG. 5, a third etching process is performed using the photoresist pattern 160 as an etching mask.

The bottom surface of the third oxide layer 156 in the spacer structure 150 on the common source region 140 is removed through the third etching process.

The third etching process can be performed through a dry etching process such as Reactive Ion Etching (RIE) technique. At this point, the third oxide layer 156 on the sidewall of the gate electrode 120 remains due to an isotropic etching characteristic. By this process the third oxide layer 156 on only the common source region 140 is removed, exposing the common source region 140 while remaining on the inner sidewalls of the gate lines 120.

The remaining portion of the third oxide layer 156 protects the inner sidewall of the gate electrode 120.

FIG. 6 is a side-sectional view taken along the line B-B′ of FIG. 1 and illustrates a structure after a silicide layer 162 is formed in a semiconductor memory device according to an embodiment.

For example, referring to FIG. 6, the photoresist pattern 160 is removed, and then a salicide process is performed to form the silicide layer 162 on the surfaces of the common source region 140, the drain region 130, and the gate electrode 120.

Deposition, thermal treatment, and removal processes of a metal layer are performed for the salicide process. For example, the silicide layer 162 may be formed of silicide combined with Group VIII metal and silicon (for example, CoSi₂, NiSi₂, PtSi, Pt₂Si, and so forth), silicide of Group IV metal (for example, TiSi₂), or silicide of a high melting point (for example, MoSi₂, TaSi₂, WSi₂, and so forth).

When the gate electrode 120, the drain region 130, and the common source region 140 electrically contact the semiconductor surface through the silicide layer 162, parasitic capacitance can be removed or substantially reduced, and also its contact resistance and drain-source internal resistance can be reduced.

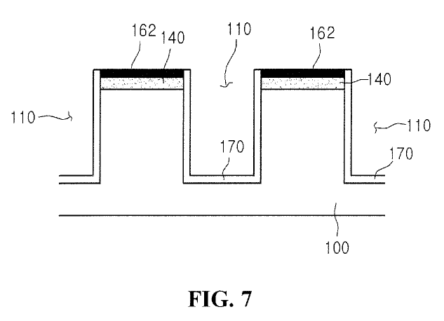

FIG. 7 is a side-sectional view taken along the line C-C′ of FIG. 1 and illustrates a structure of a semiconductor memory device according to an embodiment.

Referring to FIG. 7, after performing the silicide process, the insulation layer in the portions of the device isolation region 110 that insulates the common source regions 140 on the x-axis is removed to be a trench, and impurity ions are implanted on the semiconductor substrate 100 in the trench 110.

Thus, an ion implantation layer 170 is formed on the inner surface of the trench 110, and serves a function of a conductive wire that electrically connects the common source regions 140.

Next, an insulation material such as BoroPhosphoSilicate Glass (BPSG) is deposited on the semiconductor substrate 100 including the gate electrode 120, the spacer 150, the remaining device isolation region 110, the ion implantation layer 170, and the silicide layer 162, in order to form an insulation layer (not shown).

The embodiments can have the following effects.

First, even if an interval between devices is reduced as a memory device is highly integrated and micronized, a silicide layer can be formed by removing a spacer influence.

Second, a resistance value can be minimized by forming a silicide layer in a common source region and a current flow of cell regions can be uniformly maintained. Therefore, the operational reliability of a semiconductor memory device can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor memory device comprising:
two gate electrodes on a semiconductor substrate between device isolation regions;
a common source region on the semiconductor substrate between the two gate electrodes;
a drain region on the semiconductor substrate at outer sides of the two gate electrodes;
a spacer on the drain region and on outer sidewalls of the two gate electrodes;
a third oxide layer on inner sidewalls of the two gate electrodes, the inner sidewalls facing each other; and
a silicide layer on the common source region.

2. The semiconductor memory device according to claim 1, wherein each of the two gate electrodes comprises: a gate electrode stack including a floating gate, an insulating layer, and a control gate.

3. The semiconductor memory device according to claim 2, wherein the insulating layer comprises an Oxide-Nitride-Oxide (ONO) structure including a first oxide layer, a first nitride layer, and a second oxide layer.

4. The semiconductor memory device according to claim 1, wherein the spacer comprises an ONO structure including the third oxide layer, a second nitride layer, and a fourth oxide layer.

5. The semiconductor memory device according to claim 1, wherein the silicide layer is further formed on the drain region and a top portion of each of the two gate electrodes.

6. The semiconductor memory device according to claim 1, wherein:
the two gate electrodes are provided as two parallel gate electrode lines;
the common source region is provided in plurality at intervals between the two parallel gate electrode lines; and
an ion implantation layer is formed in a trench located between each common source region of the plurality of common source regions, the ion implantation layer electrically connecting the plurality of common source regions on an axis parallel to the two parallel gate electrode lines.

7. The semiconductor memory device according to claim 6, further comprising an insulation layer on the semiconductor substrate, including the gate electrode lines, the spacer, the device isolation regions, the ion implantation layer in the trench, and the silicide layer.

8. A method of manufacturing a semiconductor memory device, the method comprising:
forming two gate electrodes on a semiconductor substrate between device isolation regions;
forming a common source region in the semiconductor substrate between the two gate electrodes and forming a drain region between outer sides of the two gate electrodes and the device isolation regions;
forming a spacer on sidewalls of the two gate electrodes, the spacer disposed on the drain region and the common source region, wherein the spacer comprises a third oxide layer, a second nitride layer, and a fourth oxide layer;
removing the fourth oxide layer and the second nitride layer formed between the two gate electrodes, and removing the third oxide layer formed on the common source region; and
forming a silicide layer on the common source region.

9. The method of claim 8, wherein the forming of the gate electrode comprises:
forming a gate electrode stack including a floating gate, ONO layer, and a control gate.

10. The method of claim 9, wherein the forming of the gate electrode comprises:
forming the ONO layer by sequentially stacking a first oxide layer, a first nitride layer, and a second oxide layer on the semiconductor substrate; and etching the first oxide layer, the first nitride layer, and the second oxide layer by using a photoresist pattern as an etching mask, the photoresist pattern defining a gate electrode region.

11. The method according to claim 8, wherein when removing the third oxide layer formed on the common source region, the third oxide layer remains on the inner sidewalls between the two gate electrodes.

12. The method according to claim 8, wherein the removing of the fourth oxide layer and the second nitride layer and the removing of the third oxide layer comprises:
forming a photoresist pattern to expose the spacer on the common source region;
removing the fourth oxide layer exposed between the two gate electrodes through a first etching process;
removing the second nitride layer exposed between the two gate electrodes through a second etching process;
removing the third oxide layer exposed on the common source region through a third etching process; and
removing the photoresist pattern.

13. The method according to claim 12, wherein the first and second etching processes use a wet etching technique, and the third etching process uses a dry etching technique.

14. The method according to claim 8, wherein the forming of the silicide layer further comprises forming the silicide layer on the drain region and a top portion of the two gate electrodes.

15. The method according to claim 8, further comprising:
removing a device insulation layer from device isolation regions insulating the common source region from adjacent common source regions between two parallel gate lines providing the two gate electrodes, thereby forming a trench in the semiconductor substrate between the two parallel gate lines at each device isolation region insulating the common source region, the device isolation regions insulating the common source region being at intervals on an axis parallel to the two parallel gate lines; and
forming an ion implantation layer in the trench of the device isolation region insulating the common source region where the device insulation layer is removed.

16. The method according to claim 15, further comprising forming an insulation layer on the semiconductor substrate, including the gate electrode, the spacer, the device isolation regions, the ion implantation layer in the trench, and the silicide layer.
